(19) United States
(12) Patent Application Publication
(10) Pub. No.: US 2024/0188366 A1
(43) Pub. Date: Jun. 6, 2024

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yongbo Wu, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/759,856

(22) PCT Filed: Jun. 30, 2022
(86) PCT No.: PCT/CN2022/103063

§ 371 Date: Dec. 21, 2023

(30) Foreign Application Priority Data
Jun. 15, 2022 (CN) 202210678535.9

(51) Int. Cl. H10K 59/38; H10K 59/126; H10K 59/80; H10K 102/00

(52) U.S. Cl. CPC H10K 59/38; H10K 59/126; H10K 59/873; H10K 2102/361

(57) ABSTRACT

A display panel is provided by the present application, the display panel includes a display area, and a non-display area located on a side of the display area, and further includes an array substrate and a color filter layer disposed on both sides of a light-emitting structure layer, the light-emitting structure layer includes light-emitting pixels located in the display area; the color filter layer includes a light-shielding part, blocking parts, and color resist parts; the light-shielding part is defined in first openings corresponding to the light-emitting pixels and in second openings defined in the non-display area; the color resist parts are located in the first openings, and the blocking parts are located in the second openings.

### BACKGROUND OF INVENTION

### Field of Invention

The present application relates to a field of display technology, and in particular to a display panel.

### Description of Prior Art

In an organic light-emitting diode (OLED) display panel, a polarizer is usually provided, but its transmittance of light is low, resulting in a poor display effect of the OLED display panel. In order to improve transmittance of light, a color filter layer is currently used to replace a traditional polarizer. The color filter layer usually includes a light-shielding part. The light-shielding part on a non-display area is usually disposed on a whole surface, because the light-shielding part is an organic photoresist, it can absorb water easily, therefore, when water vapor from an outside intrudes into the non-display area, under an effect of high temperature, a black matrix part is easily peeled off from other film layers in the OLED display panel, thereby generating air bubbles, and as a result, the water vapor easily intrudes from the non-display area to a film layer structure in the display area, causing abnormality in the film layer structure in the display area, resulting in poor display effect of the OLED display panel.

### SUMMARY OF INVENTION

Embodiments of the present application provide a display panel to reduce a risk of external water vapor intruding a display area from a non-display area of the display panel.

The present application provides a display panel, wherein the display panel includes a display area and at least one non-display area is disposed on a side of the display area, the display panel includes:
an array substrate;
a light-emitting structure layer, the light-emitting structure layer disposed on a side of the array substrate, and the light-emitting structure layer including a plurality of light-emitting pixels disposed in the display area;
an encapsulation layer, the encapsulation layer disposed on a side of the light-emitting structure layer away from the array substrate; and
a color filter layer, the color filter layer disposed on a side of the encapsulation layer away from the array substrate;
wherein, the color filter layer includes a light-shielding part, blocking parts and color resist parts; the light-shielding part includes first openings defined in the display area and corresponding to the plurality of light-emitting pixels, and second openings defined in the non-display area; the color resist parts are disposed at least in the first openings, and the blocking parts are disposed at least in the second openings.

Optionally, in the embodiments of the present application, the blocking parts include a water-absorbing material.

Optionally, in the embodiments of the present application, the blocking parts include a same material as the color resist parts.

Optionally, in the embodiments of the present application, one of the light-emitting pixels includes a first sub-pixel displaying a first color, a second sub-pixel displaying a second color, and a third sub-pixel displaying a third color, and the first color, the second color, and the third color are different; and
the color resist parts include first color resists corresponding to the first sub-pixel, second color resists corresponding to the second sub-pixel, and third color resists corresponding to the third sub-pixel, and a material of the first color resists, a material of the second color resists, and a material of the third color resists are all different; a material of the blocking parts includes at least one of the material of the first color resists, the material of the second color resists, and the material of the third color resists.

Optionally, in the embodiments of the present application, the blocking parts include at least one first subsection and at least one second subsection, the first subsection is disposed in one of the second openings, and the second subsection is disposed in one of the second openings, the second subsection and the first subsection are disposed in a same layer and are spaced apart, a material of the second subsection is same as the material of the second color resists, and a material of the first subsection is same as the material of the first color resists.

Optionally, in the embodiments of the present application, the blocking parts further include at least one third subsection, the third subsection is disposed in one of the second openings, the third subsection, the second subsection, and the first subsection are disposed in a same layer and are spaced apart, and a material of the third subsection is same as the material of the third color resists.

Optionally, in the embodiments of the present application, the first subsection is composed of a plurality of first protection parts arranged at intervals, the second subsection is composed of a plurality of second protection parts arranged at intervals, and the third subsection is composed of a plurality of third protection parts arranged at intervals, each of the first protection parts and two adjacent ones of the second protection parts are at least partially staggered, each of the second protection parts and two adjacent ones of the third protection parts are at least partially staggered, and each of the third protection parts corresponds with one of the first protection parts.

Optionally, in the embodiments of the present application, the blocking parts further include at least one first subsection and at least one second subsection, the second subsection and the first subsection are in contact and disposed in a same layer and in one of the second openings, a material of the second subsection is same as the material of the second color resists, and a material of the first subsection is same as the material of the first color resists.

Optionally, in the embodiments of the present application, the blocking parts further include at least one third subsection, the third subsection, the second subsection, and the first subsection are in contact and disposed in a same layer in one of the second openings, the second subsection is disposed between the third subsection and the first subsection, and a material of the third subsection is same as the material of the third color resists.

Optionally, in the embodiments of the present application, the first subsection is composed of a plurality of connected first protection parts, the second subsection is composed of a plurality of connected second protection parts, and the third subsection is composed of a plurality of connected third protection parts.

The present application also provides a display panel, wherein the display panel includes a display area and at least one non-display area is disposed on a side of the display area, the display panel includes:
an array substrate;
a light-emitting structure layer, the light-emitting structure layer disposed on a side of the array substrate, and the light-emitting structure layer including a plurality of light-emitting pixels disposed in the display area; and
a color filter layer, the color filter layer disposed on a side of the light-emitting structure layer away from the array substrate,
wherein, the color filter layer includes a light-shielding part, blocking parts and color resist parts; the light-shielding part includes first openings defined in the display area and corresponding to the plurality of light-emitting pixels, and second openings defined in the non-display area; the color resist parts are disposed at least in the first openings, and the blocking parts are disposed at least in the second openings.

Optionally, in the embodiments of the present application, the blocking parts include a water-absorbing material.

Optionally, in the embodiments of the present application, the blocking parts include a same material as the color resist parts.

Optionally, in the embodiments of the present application, one of the light-emitting pixels includes a first sub-pixel displaying a first color, a second sub-pixel displaying a second color, and a third sub-pixel displaying a third color, the first color, the second color, and the third color are different;
the color resist parts include first color resists corresponding to the first sub-pixel, second color resists corresponding to the second sub-pixel, and third color resists corresponding to the third sub-pixel, a material of the first color resists, a material of the second color resists, and a material of the third color resists are all different; a material of the blocking parts includes at least one of the material of the first color resists, the material of the second color resists, and the material of the third color resists.

Optionally, in the embodiments of the present application, the blocking parts include at least one first subsection and at least one second subsection, the first subsection is disposed in one of the second openings, and the second subsection is disposed in one of the second openings, the second subsection and the first subsection are disposed in a same layer and are spaced apart, the material of the second subsection is same as the material of the second color resists, and the material of the first subsection is same as the material of the first color resists.

Optionally, in the embodiments of the present application, the blocking parts further include at least one third subsection, the third subsection is disposed in one of the second openings, the third subsection, the second subsection, and the first subsection are disposed in a same layer and are spaced apart, and a material of the third subsection is same as the material of the third color resists.

Optionally, in the embodiments of the present application, the first subsection is composed of a plurality of first protection parts arranged at intervals, the second subsection is composed of a plurality of second protection parts arranged at intervals, and the third subsection is composed of a plurality of third protection parts arranged at intervals, each of the first protection parts and two adjacent ones of the second protection parts are at least partially staggered, each of the second protection parts and two adjacent ones of the third protection parts are at least partially staggered, and each of the third protection parts corresponds with one of the first protection parts.

Optionally, in the embodiments of the present application, the blocking parts further include at least one first subsection and at least one second subsection, the second subsection and the first subsection are in contact and disposed in a same layer and in one of the second openings, a material of the second subsection is same as a material of the second color resists, and a material of the first subsection is same as a material of the first color resists.

Optionally, in the embodiments of the present application, the blocking parts further include at least one third subsection, the third subsection, the second subsection, and the first subsection are in contact and disposed in a same layer and in one of the second openings, the second subsection is disposed between the third subsection and the first subsection, and a material of the third subsection is same as the material of the third color resists.

Optionally, in the embodiments of the present application, the first subsection is composed of a plurality of connected first protection parts, the second subsection is composed of a plurality of connected second protection parts, and the third subsection is composed of a plurality of connected third protection parts.

### Advantageous Effects

The present application provides the display panel, the display panel includes the display area and the at least one non-display area disposed on the side of the display area, The display panel includes the array substrate, the light-emitting structure layer and the color filter layer, the light-emitting structure layer is disposed on the side of the array substrate, and the light-emitting structure layer includes the plurality of light-emitting pixels disposed in the display area; the color filter layer is disposed on the side of the light-emitting structure layer away from the array substrate, wherein the color filter layer includes the light-shielding part, the blocking parts and the color-resist parts; the light-shielding part includes the first openings defined in the display area and corresponding to the light-emitting pixels, and the second openings defined in the non-display area; the color resist parts are disposed in the first openings at least, and the blocking parts are disposed in the second openings at least. In the present application, in the non-display area, by setting the blocking parts in the light-shielding part, the blocking parts can block water vapor in the non-display area, reducing a risk of the water vapor entering the display area from the non-display area, thereby ensuring a performance of the display panel.

### BRIEF DESCRIPTION OF DRAWINGS

In order to more clearly illustrate the embodiments or the technical solutions of the existing art, the drawings illustrating the embodiments, or the existing art will be briefly described below. The drawings in the following description merely illustrate some embodiments of the present application. Other drawings may also be obtained by those skilled in the art according to these figures without paying creative work.

FIG. 1 is a first schematic plan view of a display panel provided by an embodiment of the present application.

FIG. 2 is a schematic cross-sectional view of the display panel in FIG. 1 along line AB.

FIG. 3 is a second schematic plan view of the display panel provided by an embodiment of the present application.

FIG. 4 is a schematic cross-sectional view of a color filter layer in a non-display area in FIG. 3 along line AB.

FIG. 5 is a third schematic plan view of the display panel provided by an embodiment of the present application.

FIG. 6 is a schematic cross-sectional view of the color filter layer in the non-display area in FIG. 5 along line AB.

FIG. 7 is a fourth schematic plan view of the display panel provided by an embodiment of the present application.

FIG. 8 is a schematic cross-sectional view of the color filter layer in the non-display area in FIG. 7 along line CD.

### REFERENCE NUMBERS

Display panel 10; display area 11; non-display area 12; array substrate 100; substrate 110; transistors 120; active part 121; gate electrode 122; gate insulating part 123; source and drain electrodes 124; interlayer dielectric layer 130; planarization layer 140; light-emitting structure layer 200; first electrodes 210; light-emitting parts 220; second electrode 230; pixel definition layer 300; encapsulation layer 400; first inorganic layer 410; organic layer 420; second inorganic layer 430; color filter layer 500; light-shielding part 510; second openings 511; first openings 512; blocking parts 520; first subsection 521; first protection parts 521a; second subsection 522; second protection parts 522a; third subsection 523; third protection parts 523a; color resist parts 530; coating layer 540.

### DETAILED DESCRIPTION OF PREFERRED EMBODIMENTS

Technical solutions in the embodiments of the present application will be clearly and completely described below with reference to the drawings in the embodiments of the present application. Obviously, the described embodiments are only a part of the embodiments of the present application, rather than all the embodiments. Based on the embodiments in the present application, all other embodiments obtained by those skilled in the art without creative work fall within the protection scope of the present application. In addition, it should be understood that the specific embodiments described herein are only used to illustrate and explain the present application, but not to limit the present application. In this application, unless otherwise stated, the directional words used such as “upper” and “lower” generally refer to the upper and lower sides of the device in actual use or working state, specifically the drawing direction in the accompanying drawings; while “inside” and “outside” refer to the outline of the device. In this application, a “reaction” may be a chemical reaction or a physical reaction.

The present application provides a display panel, the display panel includes a display area, and at least one non-display area disposed on a side of the display area, the display panel includes an array substrate, a light-emitting structure layer, and a color filter layer. The light-emitting structure layer is disposed on a side of the array substrate. The light-emitting structure layer includes a plurality of light-emitting pixels disposed in the display area. The color filter layer is disposed on a side of the light-emitting structure layer away from the array substrate. Wherein, the color filter layer includes a light-shielding part, blocking parts, and color resist parts. The light-shielding part includes first openings defined in the display area and corresponding to the plurality of light-emitting pixels, and second openings defined in the non-display area; the color resist parts are disposed at least in the first openings. The blocking parts are disposed at least in the second openings.

In the present application, in the non-display area, by setting the blocking parts in the light-shielding part, due to a blocking effect of the blocking parts, water vapor can be blocked in the non-display area, reducing a risk of the water vapor entering the display area from the non-display area, thereby reducing a risk of film layers in the display area being intruded by the water vapor, thereby ensuring a performance of the display panel.

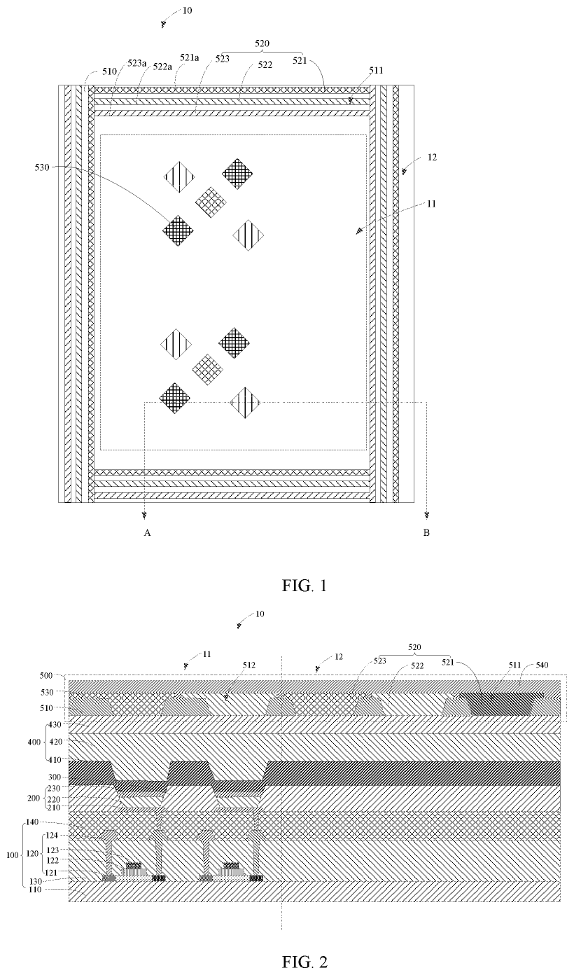

Please refer to FIG. 1 and FIG. 2, the present application provides a display panel 10. The display panel includes a display area 11, and at least one non-display area 12 disposed on a side of the display area 11. The display panel 10 includes an array substrate 100, a light-emitting structure layer 200, a pixel definition layer 300, an encapsulation layer 400, and a color filter layer 500. A detailed description will be given below.

The display panel of the present application is an organic light-emitting diode (OLED) display panel, and may also be another display panel 10, which is not limited to these.

Please continue to refer to FIG. 1 and FIG. 2, the array substrate 100 includes a substrate 110, and a transistor layer disposed on the substrate 110. The substrate 110 may be a rigid substrate or a flexible substrate. The rigid substrate is a glass substrate. The flexible substrate is a polyimide substrate. The transistor layer includes transistors 120, an interlayer dielectric layer 130, and a planarization layer 140. There are a plurality of transistors 120. The transistors 120 are located in the display area 11. One of the transistors 120 includes an active part 121, a gate electrode 122, a gate insulating part 123, and a source and drain electrode 124. The active part 121 is disposed on the substrate 110. The active part 121 includes a semiconductor part, and conductor parts disposed on both sides of the semiconductor part. The conductor parts are formed by subjecting the semiconductor part to a conductorization process. Specifically, the conductor parts are P-type doped and/or N-type doped. The gate electrode 122 and the gate insulating part 123 are sequentially stacked on the active part 121 and correspond to the semiconductor part. The interlayer dielectric layer 130 is disposed on the substrate 110, the active part 121, the gate electrode 122, and the gate insulating part 123. The interlayer dielectric layer 130 is disposed in the display area 11 and the non-display area 12. The interlayer dielectric layer 130 is defined with first connection holes. The first connection holes penetrate through the interlayer dielectric layer 130 to expose the conductor parts. The source and drain electrodes 124 are disposed on the interlayer dielectric layer 130 and extend into the first connection holes to be connected to the conductor parts. The planarization layer 140 is disposed on a side of the interlayer dielectric layer 130 away from the substrate 110. The planarization layer 140 is disposed in the display area 11 and the non-display area 12. The planarization layer 140 is defined with second connection holes. The second connection holes penetrate through the planarization layer 140 to expose the source and drain electrodes 124.

Please continue to refer to FIG. 1 and FIG. 2, the light-emitting structure layer 200 is disposed on a side of the array substrate 100. The light-emitting structure layer 200 includes a plurality of light-emitting pixels disposed in the display area 11. Specifically, each of the light-emitting pixels includes a first sub-pixel displaying a first color, a second sub-pixel displaying a second color, and a third sub-pixel displaying a third color. The first color, the second color, and the third color are all different. The first sub-pixel, the second sub-pixel, and the third sub-pixel all include first electrodes 210, light-emitting parts 220, and a second electrode 230. The first electrodes 210 are disposed on a side of the planarization layer 140 away from the substrate 110 and extend into the second connection holes to be connected to the source and drain electrodes 124. The pixel definition layer 300 is disposed on a side of the planarization layer 140 away from the substrate 110 and is also disposed on a side of the first electrodes 210 away from the substrate 110. The pixel definition layer 300 includes third connection holes. The third connection holes penetrate through the pixel definition layer 300 to expose the first electrodes 210. The light-emitting parts 220 are disposed on the first electrodes 210 and located in the third connection holes. The light-emitting parts 220 are an organic light-emitting diode. The organic light-emitting diode includes at least one of a red organic light-emitting diode, a blue organic light-emitting diode, and a green organic light-emitting diode. The second electrode 230 is disposed on a side of the light-emitting parts 220 away from the substrate 110. The second electrode 230 is an anode and the first electrodes 210 are a cathode, or the second electrode 230 is the cathode and the first electrodes 210s are the anode.

In one embodiment, if the light-emitting parts of the first sub-pixel is the red organic light-emitting diode, the first sub-pixel is a red sub-pixel, and a first color displayed is red. If the light-emitting parts of the second sub-pixel is the green organic light-emitting diode, the second sub-pixel is a green sub-pixel, and a second color displayed is green. If the light-emitting parts of the third sub-pixel is the blue organic light-emitting diode, the third sub-pixel is a blue sub-pixel, and a third color displayed is blue. Of course, the light-emitting parts of the first sub-pixel may also be the organic light-emitting diode of other colors, which is not limited here.

Please continue to refer to FIG. 1 and FIG. 2, the encapsulation layer 400 is disposed on a side of the light-emitting structure layer 200 away from the array substrate 100. Specifically, the encapsulation layer 400 includes a first inorganic layer 410, an organic layer 420, and a second inorganic layer 430. The first inorganic layer 410 is disposed on a side of the pixel definition layer 300 away from the array substrate 100 and on a side of the second electrode 230 away from the array substrate 100. The organic layer 420 and the second inorganic layer 430 are sequentially stacked and disposed on a side of the first inorganic layer 410 away from the array substrate 100.

Please continue to refer to FIG. 1 and FIG. 2, the color filter layer 500 is disposed on a side of the light-emitting structure layer 200 away from the array substrate 100. Wherein, the color filter layer 500 includes a light-shielding part 510, blocking parts 520, and color resist parts 530. The light-shielding part 510 includes first openings 512 defined in the display area 11 and corresponding to the light-emitting pixels, and second openings 511 disposed in the non-display area 12; the color resist parts 530 are disposed at least in the first openings 512, and the blocking parts 520 are disposed at least in the second openings 511. Specifically, the color filter layer 500 includes the light-shielding part 510, the color resist parts 530, the blocking parts 520 and, a coating layer 540. The light-shielding part 510 is disposed on a side of the second inorganic layer 430 away from the substrate 100. The light-shielding part 510 is located in the display area 11 and the non-display area 12. The light-shielding part 510 is defined with the second openings 511 and the first openings 512. Both the second openings 511 and the first openings 512 penetrate through the light-shielding part 510 to expose the second inorganic layer 430. The light-shielding part 510 is divided into a plurality of black parts by the second openings 511 and the first openings 512. The second openings 511 are located in the non-display area 12. The first openings 512 are located in the display area 11. The blocking parts 520 are disposed on the light-shielding part 510 and extend into the second openings 511. The color resist parts 530 are disposed on the light-shielding part 510 and extend into the first openings 512. The color resist parts 530 include first color resists corresponding to the first sub-pixel, second color resists corresponding to the second sub-pixel, and third color resists corresponding to the third sub-pixel. A material of the first color resists, a material of the second color resists and a material of the third color resists are all different. A material of the blocking parts includes at least one of the material of the first color resists, the material of the second color resists, and the material of the third color resists. The first color resists, the second color resists, and the third color resists are all arranged at intervals. The coating layer 540 is disposed on the light-shielding part 510, the color resist parts 530, and the blocking parts 520.

In one embodiment, the first color resists are red color resists. The second color resists are green color resists. The third color resists are blue color resists. Optionally, the first color resists can also be the green color resists. The second color resists can also be the blue color resists. The third color resists can also be the red color resists. It can also be others, which is not limited here. In this embodiment, the first color resists are the red color resists, the second color resists are the green color resists, and the third color resists are the blue color resists as an example for description.

In the prior art, the light-shielding part on a side of the non-display area is usually disposed on an entire surface. Because the light-shielding part is an organic photoresist, it easily absorbs water, therefore, when external water vapor intrudes into the non-display area, under an effect of high temperature, the light-shielding part is easily peeled off from other film layers in the display panel, thereby generating air bubbles, as a result, the water vapor easily intrudes from the non-display area to a film layer structure in the display area, causing abnormality in the film layer structure in the display area, resulting in poor display effect of the display panel. In the present application, by defining the second openings 511 in the light-shielding part 510 of the non-display area 12, and setting the blocking parts 520 in the second openings 511, the shielding part 510 is not disposed on the entire surface, reducing a risk of the water vapor intruding into the display area 11 from the side of the non-display area 12 due to a blocking effect of the blocking parts 520, thereby ensuring performance of the film layer structure in the display area 11, thereby ensuring display effect of the display panel 10.

Please continue to refer to FIG. 1 and FIG. 2, in one embodiment, there are a plurality of blocking parts 520. Two adjacent ones of the blocking parts 520 are arranged at intervals or in contact, so that the non-display area 12 has multiple barrier interfaces, thereby further reducing the risk of the water vapor intruding into the display area 11 from the side of the non-display area 12.

Please continue to refer to FIG. 1 and FIG. 2, in one embodiment, a water vapor blocking performance of the blocking parts 520 is greater than a water vapor blocking performance of the light-shielding part 510.

In the present application, because the water vapor blocking performance of the blocking parts 520 is greater than the water vapor blocking performance of the light-shielding part 510, the risk of the water vapor intruding from the non-display area 12 to the display area 11 is further reduced.

Please continue to refer to FIG. 1 and FIG. 2, in one embodiment, the blocking parts 520 include a same material as the color resist parts, that is, the blocking parts 520 and the color resist parts 530 are both formed of the same material. A material of the color resist parts 530 is formed of a mixture containing phenolic resins, and the mixture containing phenolic resins contains pigments.

In the present application, the blocking parts 520 and the color resist parts 530 are both formed of the same material, so that the blocking parts 520 and the color resist parts 530 can be formed simultaneously, simplifying a manufacturing process of the display panel 10, thereby shortening a production cycle and reducing cost. At a same time, because the mixture containing phenolic resins has a water-absorbing effect, an external water vapor is absorbed by the blocking parts on the non-display area 12, preventing the external water vapor from the display area 11 intruding into the non-display area 12, and the film layers in the display area 11 is prevented from being intruded by the water vapor.

Please continue to refer to FIG. 1 and FIG. 2, in one embodiment, the blocking parts 520 include at least one first subsection 521. The first subsection 521 is disposed in one of the second openings 511. A material of the first subsection 521 is same as the material of the first color resists.

In the present application, the first subsection 521 is disposed in one of the second openings 511, so that three layers of barrier interfaces for blocking the water vapor are formed on the non-display area 12, and the three layers of barrier interfaces are the first subsection 521 and black parts on both sides of the first subsection 521, that is, there is a “layer-by-layer barrier” between the non-display area 12 and the display area 11, thereby further reducing the risk of water vapor intruding into the display area 11 from the side surface of the non-display area 12. Since the material of the first subsection 521 is same as the material of the first color resists, the first subsection 521 and the first color resists are formed simultaneously, thereby simplifying the manufacturing process of the display panel 10.

Please continue to refer to FIG. 1 and FIG. 2, in one embodiment, the blocking parts 520 further include at least one second subsection 522. The second subsection 522 is disposed in one of the second openings 511. The second subsection 522 and the first subsection 521 are disposed in a same layer and are spaced apart. A material of the second subsection 522 is same as the material of the second color resists.

In the present application, by setting the second subsection 522 on a basis of the first subsection 521, more barrier interfaces with different water vapor barrier properties are formed on the non-display area 12, the risk of the water vapor intruding from the non-display area 12 to the display area 11 is reduced, thereby ensuring the performance of the film layer structure in the display area 11, and thus ensuring the performance of the display panel 10. Since the material of the second subsection 522 is the same as the material of the second color resists, the second subsection 522 and the second color resists are formed simultaneously, which can simplify the manufacturing process of the display panel 10.

Please continue to refer to FIG. 1 and FIG. 2, in one embodiment, the first subsection 521 is located on a side of the second subsection 522 away from the display area 11. A water vapor barrier performance of the first subsection 521 is greater than a water vapor barrier performance of the second subsection 522.

In the present application, since the water vapor barrier performance of the first subsection 521 is greater than the water vapor barrier performance of the second subsection 522, most of the external water vapor from is absorbed by the first subsection 521, and only a small part of the water vapor will approach a second part through the first subsection 521; and because the second subsection 522 is disposed between the first subsection 521 and the display area 11, the second subsection 522 can block the small part of the water vapor out of the display area 11, thereby reducing the risk of the film layer in the display area 11 being intruded by the water vapor, thereby further ensuring the performance of the display panel 10.

Please continue to refer to FIG. 1 and FIG. 2, in one embodiment, the blocking parts 520 further include at least one third subsection 523. The third subsection 523 is disposed in one of the second openings 511. The third subsection 523 is disposed in a same layer as the second subsection 522 and the first subsection 521, and are spaced apart. A material of the third subsection 523 is same as the material of the third color resists.

In the present application, by setting the third subsection 523 on a basis of the first subsection 521 and the second subsection 522, so that more barriers with different water vapor blocking properties are formed on the non-display area 12, reducing the risk of water vapor intruding from the non-display area 12 to the display area 11, thereby ensuring the performance of the film layer structure in the display area 11, and thus ensuring the performance of the display panel 10. Since the material of the third subsection 523 is the same as the material of the third color resist, the third subsection 523 and the third color resists can be formed simultaneously, which can simplify the manufacturing process.

Please continue to refer to FIG. 1 and FIG. 2, in one embodiment, the second subsection 522 is located between the first subsection 521 and the third subsection 523. The first subsection 521 is located on the side of the second subsection 522 away from the display area 11. The water vapor barrier performance of the first subsection 521 is greater than the water vapor barrier performance of the second subsection 522. The water vapor barrier performance of the second subsection 522 is greater than a water vapor barrier performance of the third subsection 523.

In the present application, by setting the water vapor barrier performance of the first subsection 521 to be greater than the water vapor barrier performance of the second subsection 522, and the water vapor barrier performance of the second subsection 522 to be greater than the water vapor barrier performance of the third subsection 523, most of the external water vapor is blocked or absorbed by the first subsection 521 and the second subsection 522, and only the small part of the water vapor will approach the third subsection 523 through the first subsection 521 and the second subsection 522, because the third subsection 523 is also disposed between the second subsection 522 and the display area 11, the small part of the water vapor can be blocked out of the display area 11, and the risk of the film layer in the display area 11 being intruded by the water vapor is reduced, thereby further ensuring the performance of the display panel 10.

Please continue to refer to FIG. 1 and FIG. 2, in one embodiment, the first subsection 521 is composed of a plurality of connected first protection parts 521a. The second subsection 522 is composed of a plurality of connected second protection parts 522a. The third subsection 523 is composed of a plurality of connected third protection parts 523a.

In this application, the first subsection 521 is configured to be composed of the plurality of connected first protection parts 521a, the second subsection 522 is configured to be composed of the plurality of connected second protection parts 522a, and the third subsection 523 is configured to be composed of the plurality of connected third protection parts 523a, so that a plurality of blocking interfaces are formed in the non-display area 12, improving the performance of water vapor blocking, and an etching precision requirement is reduced at a same time, thereby reducing the cost.

Please continue to refer to FIG. 1 and FIG. 2, in one embodiment, non-display areas 12 are provided around the display area 11, that is, the display panel 10 includes four of the non-display areas 12. Each of the non-display areas 12 is disposed with the light-shielding part 510, and the blocking parts 520 disposed in the light-shielding part 510.

In the present application, by setting the blocking parts 520 on the non-display areas 12 around the display area 11, the blocking parts 520 can block the water vapor around the display area 11, reducing the risk of the external water vapor intruding the display area 11 from the non-display areas 12, and ensuring the performance of the film structure in the display area 11, thereby ensuring the performance of the display panel 10.

It should be noted that, structures in the present application may be removed as required, such as removing the encapsulation layer 400, the planarization layer 140, or the interlayer dielectric layer 130 and the like.

In another embodiment, the material of the blocking parts 520 includes a water-absorbing material, and the material of the blocking parts 520 is selected from at least one of silicon nitride, silicon oxide, water-based polyurethane, and polyaluminum sulfate. That is, the material of the blocking parts 520 is different from the material of the color resist parts 530, that is, the color resist parts 530 and the blocking parts 520 are not formed simultaneously. In the present application, since a cost of using silicon nitride, silicon oxide, water-based polyurethane, and polyaluminum sulfate is low, these materials are used to form the blocking parts 520, which can block the intrusion of the external water vapor into the display area 11 from the non-display area 12, the risk of the water vapor intruding from the non-display area 12 to the display area 11 can be further reduced, thereby further ensuring the display effect of the display panel 10.

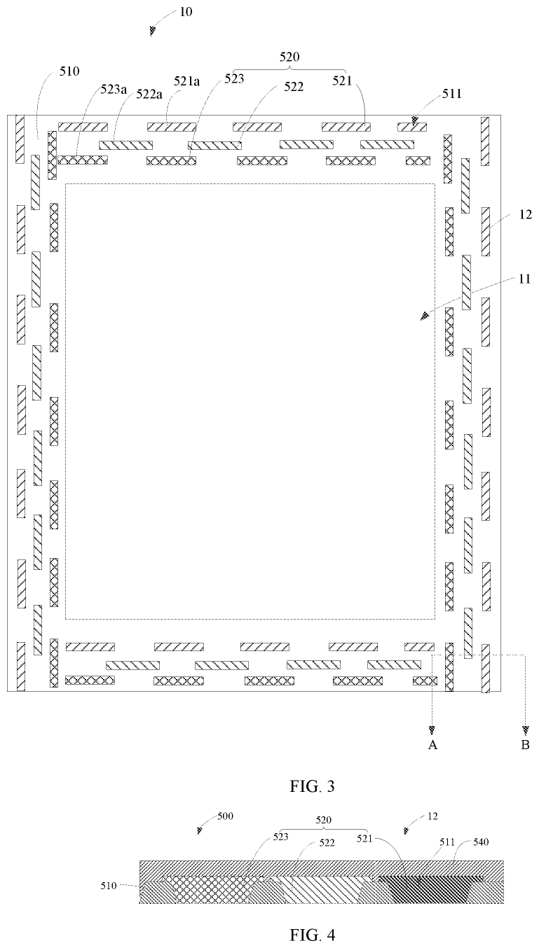

Please refer to FIG. 3 and FIG. 4, it should be noted that, a difference between a second structure and a first structure is:

The first subsection 521 is composed of the plurality of first protection parts 521a arranged at intervals. The second subsection 522 is composed of the plurality of second protection parts 522a arranged at intervals. The third subsection 523 is composed of the plurality of third protection parts 523a arranged at intervals. Each of the first protection parts 521a and two adjacent ones of the second protection parts 522a are at least partially staggered. Each of the second protection parts 522a and two adjacent ones of the third protection parts 523a are at least partially staggered, and each of the third protection parts 523a corresponds with one of the first protection parts 521a.

In the present application, the first subsection 521, the second subsection 522, and the third subsection 523 are all formed by a plurality of protection parts spaced apart, and each of the first protection parts 521a and the two adjacent ones of the second protection parts 522a are at least partially staggered, and each of the second protection parts 522a and the two adjacent ones of the third protection parts 523a are at least partially staggered, and each of the third protection parts 523a corresponds with the one of the first protection parts 521a, so that the plurality of blocking interfaces are formed in the non-display area 12, It can reduce the cost while blocking the water vapor.

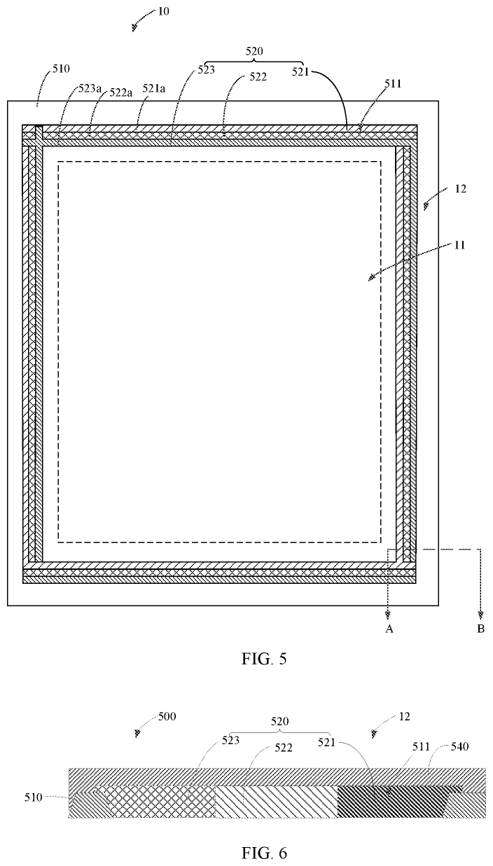

Please refer to FIG. 5 and FIG. 6, it should be noted that, a difference between a third structure and the first structure is:

The blocking parts 520 further include the at least one second subsection 522, the second subsection 522 and the first subsection 521 are in contact and are disposed in a same layer in one of the second openings 511, the material of the second subsection 522 and the material of the first subsection 521 are different.

In the present application, by contacting the second subsection 522 with the first subsection 521 and disposing in the same layer in the one of the second openings 511, the intrusion of the external water vapor from the side of the non-display area 12 into the display area 11 is reduced, at the same time, the etching precision requirement of the second opening 511 is reduced, thereby reducing the cost and ensuring the performance of the display panel 10.

In one embodiment, a width of one of the second openings disposed with a subsection is less than a width of one of the second openings disposed with a plurality of subsections. Specifically, when the first subsection 521 is disposed in one of the second openings 511 or the second subsection 522 is disposed in one of the second openings 511, the one of the second openings 511 includes a first width; when the first subsection 521 and the second subsection 522 are disposed in one of the second openings 511, the one of the second openings 511 includes a second width. The second width is greater than the first width. That is, the more subsections disposed in one of the second openings 511, the width of one of the second openings 511 also increases with an increase of a number of subsections.

In the present application, by setting the width of one of the second openings disposed with one subsection to be less than the width of one of the second openings disposed with the plurality of subsections, so that when the external water vapor enters the display area 11, it needs to pass through a relatively long path, thereby further reducing the risk of intrusion of the external water vapor from the non-display area 12 to the display area 11.

In another embodiment, the width of one of the second openings disposed with one subsection is equal to the width of one of the second openings disposed with the plurality of subsections. Specifically, when the first subsection 521 is disposed in one of the second openings 511 or the second subsection 522 is disposed in one of the second openings 511, the one of the second openings 511 includes the first width; when the first subsection 521 and the second subsection 522 are disposed in one of the second openings 511, the one of the second openings 511 includes the second width. The second width is equal to the first width.

In the present application, the width of the one of the second openings disposed with one subsection is equal to the width of the one of the second openings disposed with the plurality of subsections, the blocking parts 520 can further reduce the risk of intrusion of the external water vapor from the non-display area 12 to the display area 11, simplifying the process of forming the second openings 11, thereby shortening the production cycle.

Please continue to refer to FIG. 5 and FIG. 6, in one embodiment, the blocking parts 520 further include at least one third subsection 523, and the third subsection 523, the second subsection 522, and the first subsection 521 are in contact and are disposed in a same layer in one of the second openings 511, the second subsection 522 is disposed between the third subsection 523 and the first subsection 521, and the material of the third subsection 523, the material of the second subsection 522, and the material of the first subsection 521 are different.

In the present application, the first subsection 521, the second subsection 522, and the third subsection 523 are all disposed in one of the second openings 511, which can further reduce the risk of intrusion of the external water vapor from the non-display area 12 to the display area 11, and at a same time, the etching precision requirement of the second openings 511 is reduced, thereby reducing the cost and ensuring the performance of the display panel 10.

In one embodiment, the width of the one of the second openings disposed with one subsection is less than the width of the one of the second openings disposed with the plurality of subsections. Specifically, when the first subsection 521 is disposed in one of the second openings 511, the second subsection 522 is disposed in one of the second openings 511, or the third subsection 523 is disposed in one of the second openings 511, the one of the second openings 511 includes the first width; when the first subsection 521, the second subsection 522, and the third subsection 523 are disposed in one of the second openings 511, the one of the second openings 511 includes a third width. The third width is greater than the first width.

In the present application, by setting the width of the one of the second openings disposed with one subsection to be less than the width of the one of the second openings disposed with the plurality of subsections, when the external water vapor enters the display area 11, it needs to go through a relatively long path, thereby further reducing the risk of the external water vapor intruding from the non-display area 12 to the display area 11.

In another embodiment, the width of the one of the second openings disposed with one subsection is equal to the width of the one of the second openings disposed with the plurality of subsections. Specifically, when the first subsection 521 is disposed in one of the second openings 511, or the second subsection 522 is disposed in one of the second openings 511, the one of the second openings 511 includes the first width; when the first subsection 521, the second subsection 522, and the third subsection 523 are disposed in one of the second openings 511, the one of the second openings 511 includes the third width. The third width is equal to the first width.

In the present application, by setting the width of the one of the second openings disposed with one subsection to be equal to the width of the one of the second openings disposed with the plurality of subsections, the blocking parts 520 can further reduce the risk of intrusion of the external water vapor from the non-display area 12 to the display area 11, simplifying the process of forming the second openings 511, thereby shortening the production cycle.

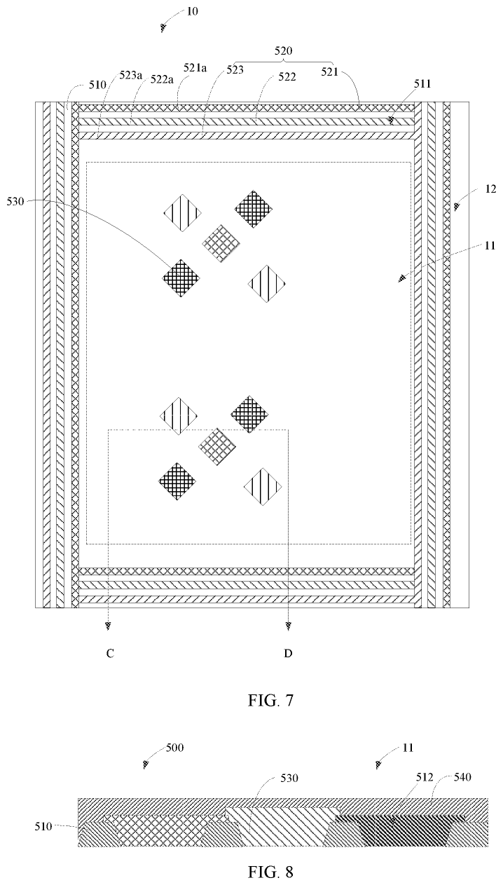

Please refer to FIG. 7 and FIG. 8, it should be noted that, a difference between a fourth structure and the first structure is:

Please continue to refer to FIG. 7 and FIG. 8, in the display area 11, the color resist parts 530 cover the light-shielding part 510. That is, two adjacent ones of the color resist parts 530 are in contact or overlap.

In the present application, because the light-shielding part 510 has a high reflectivity to light, the color resist parts 530 cover the light-shielding part 510, so as to prevent external light from irradiating the light-shielding part 510, thereby reducing the light reflectivity, at a same time, the color resist parts 530 are prevented from reacting with the light-shielding part 510 due to contact, so that an adhesion of the color resist part 530 is reduced, and the risk of the color resist parts 530 peeling off is reduced, thereby ensuring the display effect of the display panel 10.

It should be noted that, the color resist parts 530 located in the display area 11 are in contact or are overlapped in a plan view, and the color resist parts 530 are drawn according to an area through which a light in the light-emitting structure layer 200 can pass. From the plan view, the color resists 530 in the display area 11 do not touch or overlap, but this does not mean that they do not.

The present application provides the display panel 10, the display panel 10 includes the display area 11, and the at least one non-display area 12 disposed on the side of the display area 11. The display panel 10 includes the array substrate 100, the light-emitting structure layer 200, and the color filter layer 500. The light-emitting structure layer 200 is disposed on the side of the array substrate 100. The light-emitting structure layer 200 includes the plurality of the light-emitting pixels disposed in the display area 11. The color filter layer 500 is disposed on the side of the light-emitting structure layer 200 away from the array substrate 100. The color filter layer 500 includes the light-shielding part 510, the blocking parts 520, and the color resist parts 530. The light-shielding part 510 includes the first openings 512 disposed in the display area 11 and corresponding to the light-emitting pixels, and the second openings 511 disposed in the non-display area 12; the color resist parts 530 are disposed at least in the first openings 512. In the present application, in the non-display area 12, by setting the blocking parts 520 in the light-shielding part 510, the light-shielding part 510 is not disposed on the entire surface, and due to the blocking effect of the blocking parts 520, the water vapor can be blocked in the non-display area 12, The risk of the water vapor entering the display area 11 from the side of the non-display area 12 is reduced, thereby reducing the risk of the film layer in the display area 11 being intruded by the water vapor, thereby ensuring the performance of the display panel 10.

The display panel provided by the embodiments of the present application has been introduced in detail above. The principles and implementations of the present application are described herein using specific examples, and the descriptions of the above embodiments are only used to help understand the methods and core ideas of the present application; meanwhile, for those skilled in the art, according to the ideas of this application, there will be changes in specific embodiments and application scopes. To sum up, the contents of this specification should not be construed as limitations on the present application.

What is claimed is:

1. A display panel, wherein the display panel comprises a display area, and at least one non-display area is disposed on a side of the display area, the display panel comprises:
an array substrate;
a light-emitting structure layer, the light-emitting structure layer disposed on a side of the array substrate, and the light-emitting structure layer comprising a plurality of light-emitting pixels disposed in the display area;
an encapsulation layer, the encapsulation layer disposed on a side of the light-emitting structure layer away from the array substrate; and
a color filter layer, the color filter layer disposed on a side of the encapsulation layer away from the array substrate;
wherein, the color filter layer comprises a light-shielding part, blocking parts, and color resist parts; the light-shielding part comprises first openings defined in the display area and corresponding to the plurality of light-emitting pixels, and second openings defined in the non-display area; the color resist parts are disposed at least in the first openings, and the blocking parts are disposed at least in the second openings.

2. The display panel according to claim 1, wherein the blocking parts comprise a water-absorbing material.

3. The display panel according to claim 1, wherein the blocking parts comprise a same material as the color resist parts.

4. The display panel according to claim 3, wherein one of the light-emitting pixels comprises a first sub-pixel displaying a first color, a second sub-pixel displaying a second color, and a third sub-pixel displaying a third color, and the first color, the second color, and the third color are different; and
the color resist parts comprise first color resists corresponding to the first sub-pixel, second color resists corresponding to the second sub-pixel, and third color resists corresponding to the third sub-pixel, a material of the first color resists, a material of the second color resists, and a material of the third color resists are all different; and a material of the blocking parts comprises at least one of the material of the first color resists, the material of the second color resists, and the material of the third color resists.

5. The display panel according to claim 4, wherein the blocking parts comprise at least one first subsection and at least one second subsection, the first subsection is disposed in one of the second openings, and the second subsection is disposed in one of the second openings, the second subsection and the first subsection are disposed in a same layer and are spaced apart, a material of the second subsection is same as the material of the second color resists, and a material of the first subsection is same as the material of the first color resists.

6. The display panel according to claim 5, wherein the blocking parts further comprise at least one third subsection, the third subsection is disposed in one of the second openings; the third subsection, the second subsection, and the first subsection are disposed in a same layer and are spaced apart; and a material of the third subsection is same as the material of the third color resists.

7. The display panel according to claim 6, wherein the first subsection is composed of a plurality of first protection parts arranged at intervals, the second subsection is composed of a plurality of second protection parts arranged at intervals, and the third subsection is composed of a plurality of third protection parts arranged at intervals, each of the first protection parts and two adjacent ones of the second protection parts are at least partially staggered, each of the second protection parts and two adjacent ones of the third protection parts are at least partially staggered, and each of the third protection parts corresponds with one of the first protection parts.

8. The display panel according to claim 4, wherein the blocking parts further comprise at least one first subsection and at least one second subsection, the second subsection and the first subsection are in contact and disposed in a same layer in one of the second openings; a material of the second subsection is same as the material of the second color resists, and a material of the first subsection is same as the material of the first color resists.

9. The display panel according to claim 8, wherein the blocking parts further comprise at least one third subsection; the third subsection, the second subsection, and the first subsection are in contact and disposed in a same layer in one of the second openings, the second subsection is disposed between the third subsection and the first subsection, and a material of the third subsection is same as the material of the third color resists.

10. The display panel according to claim 6, wherein the first subsection is composed of a plurality of connected first protection parts, the second subsection is composed of a plurality of connected second protection parts, and the third subsection is composed of a plurality of connected third protection parts.

11. A display panel, wherein the display panel comprises a display area, and at least one non-display area is disposed on a side of the display area, the display panel comprises:
an array substrate;
a light-emitting structure layer, the light-emitting structure layer disposed on a side of the array substrate, and the light-emitting structure layer comprising a plurality of light-emitting pixels disposed in the display area; and
a color filter layer, the color filter layer disposed on a side of the light-emitting structure layer away from the array substrate,
wherein, the color filter layer comprises a light-shielding part, blocking parts, and color resist parts; the light-shielding part comprises first openings defined in the display area and corresponding to the plurality of light-emitting pixels, and second openings defined in the non-display area; the color resist parts are disposed at least in the first openings, and the blocking parts are disposed at least in the second openings.

12. The display panel according to claim 11, wherein the blocking parts comprise a water-absorbing material.

13. The display panel according to claim 11, wherein the blocking parts comprise a same material as the color resist parts.

14. The display panel according to claim 13, wherein one of the light-emitting pixels comprises a first sub-pixel displaying a first color, a second sub-pixel displaying a second color, and a third sub-pixel displaying a third color; and the first color, the second color, and the third color are different; and
the color resist parts comprise first color resists corresponding to the first sub-pixel, second color resists corresponding to the second sub-pixel, and third color resists corresponding to the third sub-pixel, a material of the first color resists, a material of the second color resists, and a material of the third color resists are all different; a material of the blocking parts comprises at least one of the material of the first color resists, the material of the second color resists, and the material of the third color resists.

15. The display panel according to claim 14, wherein the blocking parts comprise at least one first subsection and at least one second subsection, the first subsection is disposed in one of the second openings, and the second subsection is disposed in one of the second openings, the second subsection and the first subsection are disposed in a same layer and are spaced apart, a material of the second subsection is same as the material of the second color resists, and a material of the first subsection is same as the material of the first color resists.

16. The display panel according to claim 15, wherein the blocking parts further comprise at least one third subsection, the third subsection is disposed in one of the second openings, the third subsection, the second subsection, and the first subsection are disposed in a same layer and are spaced apart, and a material of the third subsection is same as the material of the third color resists.

17. The display panel according to claim 16, wherein the first subsection is composed of a plurality of first protection parts arranged at intervals, the second subsection is composed of a plurality of second protection parts arranged at intervals, and the third subsection is composed of a plurality of third protection parts arranged at intervals, each of the first protection parts and two adjacent ones of the second protection parts are at least partially staggered, each of the second protection parts and two adjacent ones of the third protection parts are at least partially staggered, and each of the third protection parts corresponds with one of the first protection parts.

18. The display panel according to claim 14, wherein the blocking parts further comprise at least one first subsection and at least one second subsection, the second subsection and the first subsection are in contact and disposed in a same layer and in one of the second openings; a material of the second subsection is same as the material of the second color resists, and a material of the first subsection is same as the material of the first color resists.

19. The display panel according to claim 18, wherein the blocking parts further comprise at least one third subsection; the third subsection, the second subsection, and the first subsection are in contact and disposed in a same layer and in one of the second openings, the second subsection is disposed between the third subsection and the first subsection, and a material of the third subsection is same as the material of the third color resists.

20. The display panel according to claim 16, wherein the first subsection is composed of a plurality of connected first protection parts, the second subsection is composed of a plurality of connected second protection parts, and the third subsection is composed of a plurality of connected third protection parts.
